(19) United States
(12) Patent Application Publication
(10) Pub. No.: US 2015/0194203 A1
(43) Pub. Date: Jul. 9, 2015

(54) STORING MEMORY WITH NEGATIVE DIFFERENTIAL RESISTANCE MATERIAL

(71) Applicant: HEWLETT-PACKARD DEVELOPMENT COMPANY, L.P., Houston, TX (US)

(72) Inventor: Matthew D. Pickett, San Francisco, CA (US)

(21) Appl. No.: 14/416,292

(22) PCT Filed: Jul. 27, 2012
(86) PCT No.: PCT/US2012/048605

§ 371 Date: Jan. 22, 2015

(51) Int. Cl. G11C 11/39; H01L 47/00; H01L 27/26

(52) U.S. Cl. CPC G11C 11/39; H01L 27/26; H01L 47/00

(57) ABSTRACT

A memory cell includes a transistor with a first source/drain terminal spaced apart from a second source/drain terminal with a semiconductor material; a gate terminal located proximate the semiconductor material such that an increase in a gate terminal voltage increases a conductivity of the semiconductor material; and the first source/drain terminal being connected in series to a negative differential resistance material.

### BACKGROUND

Many computer products use static random access memory (SRAM) and dynamic random access memory (DRAM). Each of these types of memory has different advantages. For example, SRAM is compatible with complementary metal oxide semiconductor (CMOS) technology and may be incorporated into processor dies. Also, DRAM has a circuitry that takes up a small footprint, and DRAM is often used in memory storage.

### BRIEF DESCRIPTION OF THE DRAWINGS

The accompanying drawings illustrate various examples of the principles described herein and are a part of the specification. The illustrated examples are merely examples and do not limit the scope of the claims.

FIG. 1 is a diagram of an illustrative transistor, according to principles described herein.

FIG. 2 is a diagram of an illustrative transistor, according to principles described herein.

FIG. 3 is a diagram of an illustrative chart schematically representing load lines, according to principles described herein.

FIG. 4 is a diagram of an illustrative signal profile, according to principles described herein.

FIG. 5 is a diagram of an illustrative signal profile, according to principles described herein.

FIG. 6 is a diagram of an illustrative signal profile, according to principles described herein.

FIG. 7 is a diagram of an illustrative signal profile, according to principles described herein.

FIG. 8 is a diagram of illustrative circuitry of a memory device, according to principles described herein.

FIG. 9 is a diagram of an illustrative method for storing memory, according to principles described herein.

FIG. 10 is a diagram of an illustrative flowchart of a process for operating a memory device, according to principles described herein.

### DETAILED DESCRIPTION

Both DRAM and SRAM have disadvantages. For example, DRAM is not CMOS compatible and as a consequence DRAM is not commercially used in processors or other chips built with CMOS technology. Further, SRAM has a footprint that may be five to ten times larger than the footprint of DRAM.

The principles described herein include a memory cell that has a negative differential resistance (NDR) material connected in series to a source/drain terminal of a transistor. NDR material may be a material that exhibits a characteristic where the material experiences a voltage drop with an increase in current for a particular current range. Such a memory cell is CMOS compatible and has a small footprint. Thus, a memory cell built in accordance with the principles described herein may result in a memory cell with the advantages of both DRAM and SRAM. Storing memory with NDR material may include holding a voltage at a first value within a first stable region of a bistable memory cell where the memory cell has a NDR material connected in series to a first source/drain terminal of a transistor and changing the voltage to a second value to switch a resistance state of the bistable memory cell.

In the following description, for purposes of explanation, numerous specific details are set forth in order to provide a thorough understanding of the present systems and methods. It will be apparent, however, to one skilled in the art that the present apparatus, systems, and methods may be practiced without these specific details. Reference in the specification to “an example” or similar language means that a particular feature, structure, or characteristic described is included in at least that one example, but not necessarily in other examples.

FIG. 1 is a diagram of an illustrative transistor (100), according to principles described herein. In this example, the transistor (100) has a first source/drain terminal (102) spaced apart from a second source/drain terminal (104). The first and second source/drain terminals (102, 104) may be made of an n-type semiconductor material. A p-type semiconductor material (106) may separate the first and second source/drain terminals (102, 104). Also, a gate terminal (110) may be located proximate the p-type semiconductor material (106). In the illustrated example, the p-type semiconductor material (106) is separated from the gate terminal (110) with a gate insulator (108). In some examples, the gate insulator is made of a metal oxide material. Further, the first source/drain terminal (102) is connected to a first vertical connector (112), and the second source/drain terminal (104) is connected to a second vertical connector (114). The first and the second vertical connectors (112, 114) may be contacts that are formed in vertical interconnect access pathways formed in other layers. In this example, a NDR material (116) is integrated into the first vertical connector (112). Another electrically conductive material (118) is deposited onto the NDR material (116) to help establish electrical connections to the transistor.

In some examples, the p-type semiconductor material (106) is made of silicon doped with a material that bonds with weakly bonded electrons in the p-type semiconductor material (106). In some examples, boron, aluminum, indium, gallium, another dopant, or combinations thereof are doped into the silicon. The overall effect of such doping causes the p-type semiconductor material (106) to have a positive charge that is capable of accepting electrons.

The n-type semiconductor material of the first and second source/drain terminals (102, 104) may be silicon doped with a material that provides a surplus of electrons in the terminals. In some examples, the material doped into the terminals is arsenic, phosphorous, bismuth, antimony, another dopant, or combinations thereof.

In some examples, in response to a positive voltage applied to the gate terminal, a field effect is created that attracts electrons into the p-type semiconductor material (106) making the p-type semiconductor material (106) electrically conductive. In some examples, the electrons are pulled from the n-type semiconductor material where a surplus of electrons is stored. In some examples, the transistor exhibits a relationship where a greater positive voltage applied to the gate terminal will attract a greater number of electrons into the p-type semiconductor material (106).

Such an arrangement of p-type semiconductor material (106) and terminals made of n-type semiconductor material may be constructed in accordance with CMOS technology. In some examples, the first source/drain terminal is electrically connected to a voltage source to supply the voltage to the transistor. However, in the absence of a voltage being applied to the gate terminal (110), current will not flow through the p-type semiconductor material (106) since the p-type semiconductor material (106) performs as an insulator without the field effect provided when a voltage is applied to the gate terminal (110).

The NDR material (116) may be a bistable material that has a first stable state that exhibits a low resistance characteristic and a second stable state that exhibits a high resistance characteristic. For example, when the NDR material (116) exhibits a high resistance state, the NDR material (116) acts as an insulator that prevents most electrical current from passing from the electrically conductive material (118) to the first vertical connector (112) in contact with the first source/drain terminal (102). When a voltage is applied to the gate terminal (110) and the NDR material (116) exhibits a high resistance characteristic a small amount of current may pass through the transistor (100). In such an example, the NDR material (116) limits the amount of current that may pass through the transistor (100).

On the other hand, when the NDR material (116) exhibits a low resistance characteristic and a positive voltage is applied to the gate terminal (110) a significantly larger amount of electrical current may pass through the transistor (100). In such an example, the p-type semiconductor material (106) may exhibit the highest resistance in the circuit, and as a consequence the p-type semiconductor material (106) may limit the amount of current through the transistor (100). In some examples, when the NDR material (116) is exhibiting the low resistance characteristic, the NDR material (116) allows a large amount of current to pass through the electrically conductive material (118) to the first vertical connector (112). Thus, the amount of voltage applied to the gate terminal (110) may be used to control the amount of current allowed through the transistor (100). For example, when no voltage is applied to the gate terminal (110), regardless of whether the NDR material (116) exhibits a high or low resistance characteristic, no current will pass through the transistor. However, when a small voltage is applied to the gate terminal (110) and the NDR material (116) exhibits a low resistance characteristic, just a small amount of current may pass through the transistor due to the low voltage applied to the gate terminal. Consequently, as the voltage applied to the gate terminal (110) is increased while the NDR material (116) exhibits a low resistance characteristic, more electrical current is allowed to pass through the transistor (100).

The second source/drain terminal (104) may be connected to a current sensor that is capable of measuring the amount of current passing through the transistor (100). For example, the current sensor may measure no current when no voltage is applied to the gate terminal (110). Further, the current sensor may measure a small amount of current when a voltage is applied to the gate terminal (110) and the NDR material (116) exhibits a high resistance characteristic. Also, the current sensor may measure a significantly larger amount of current when a voltage is applied to the gate terminal (110) and the NDR material exhibits a low resistance.

Such a transistor with NDR material connected in series to a source/drain terminal may be used as a memory cell. To write to the memory cell, the resistance state of the NDR material (116) may be changed. To read the information stored in the memory cell, voltage may be temporarily applied to the gate terminal (110) and the current may be measured with the current sensor. If the current sensor measures a low amount of current, such as when the NDR material exhibits a high resistance, the memory cell may be storing a “0” in binary information. On the other hand, if the current sensor measures a significantly higher amount of current, such as when the NDR material (116) exhibits a low resistance characteristic, then the memory cell may be storing a “1” in binary information.

In some examples, the NDR material is a metal selected from a group consisting of niobium, titanium, tungsten, manganese, iron, vanadium, oxides thereof, nitrides thereof, doped alloys thereof, and combinations thereof. In some examples, the NDR material includes chromium doped vanadium oxide. In some examples, the NDR material is a metal to insulator transition (MIT) material. MIT material may have two independent stable resistance states or phases that correspond to whether the MIT material's internal temperature is above or below a transition temperature. One resistance phase is a metallic or conductive phase in which the MIT material exhibits a low resistance similar to metals, thus having a high conductivity. The other resistance phase is an insulator phase in which the MIT material exhibits a resistance similar to insulators.

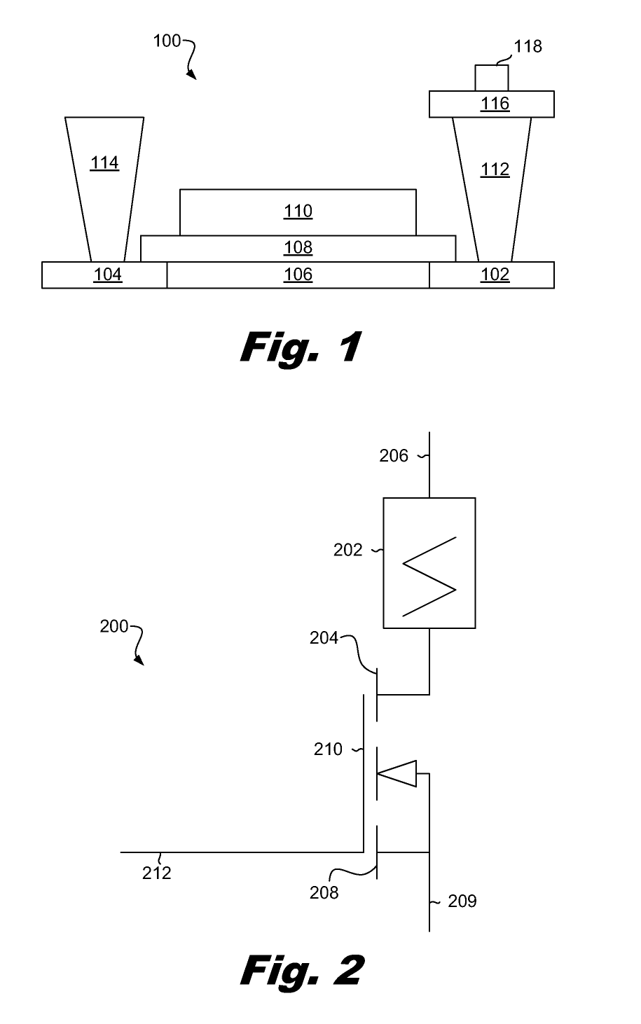

FIG. 2 is a diagram of an illustrative transistor (200), according to principles described herein. Here, the transistor (200) and the NDR material (202) are schematically represented. In some examples, the first source/drain terminal (204) is electrically connected to the NDR material (202), which may be in turn electrically connected a write line (206). Also, the second source/drain terminal (208) may be electrically connected to a bit line (209) used to select the transistor in a memory array. Also, the gate terminal (210) may be electrically connected to a read enable line (212).

The NDR material may be arranged vertically above the substrate and thereby allow for a small overall footprint of the memory cell on the substrate. As a consequence, the principles described herein may be used in applications where circuitry space is limited, such as on a processor die.

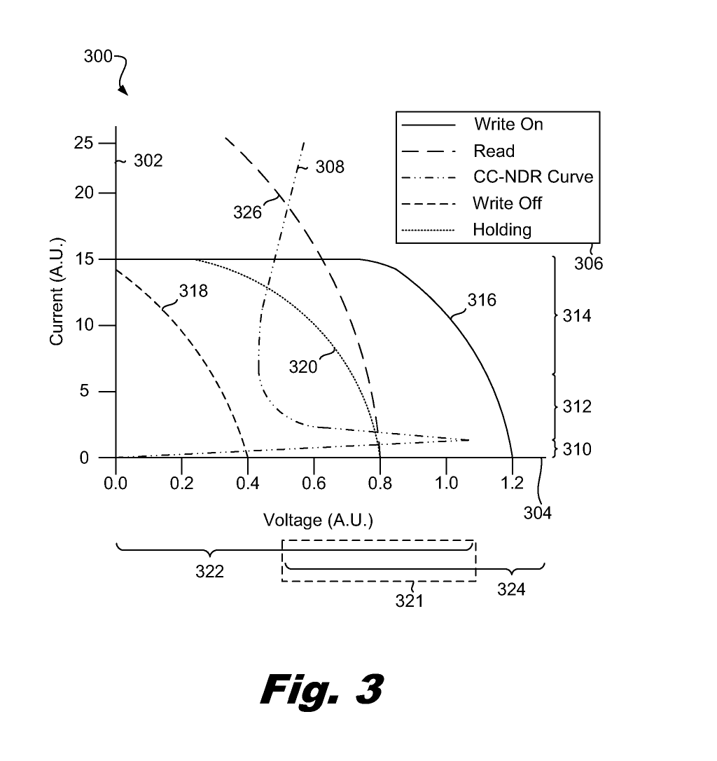

FIG. 3 is a diagram of an illustrative chart (300) schematically representing load lines of a memory cell, according to principles described herein. In this example, the y-axis (302) schematically represents current in arbitrary units, and the x-axis (304) schematically represents voltage in arbitrary units. A legend (306) indicates what each line schematically represents.

For examples, line (308) represents the current-voltage relationship of the NDR material. In this example, the NDR material is a current controlled NDR material. Line (308) schematically represents that the NDR material has a stable high resistance region (310), an instable negative region (312), and a stable low resistance region (314).

In the example of FIG. 3, in the high resistance region (310), the NDR material exhibits a high resistance characteristic where an incremental increase in voltage is accompanied with a disproportionately small increase in current. Whereas, in the low resistance region (314), the NDR material exhibits a low resistance characteristic where an incremental increase in voltage is accompanied with a disproportionately large increase in current. In the negative resistance region (312), the NDR material exhibits a characteristic where the current increases as the voltage drops. Within this region (312), the NDR material is not stable. As a consequence, the NDR material will likely exhibit the characteristics associated with either the high resistance region (310) or the low resistance region (314).

In some examples, to hold the NDR material within its existing state, the voltage is kept within the state's associated stable region. For example, to hold a NDR material that is schematically represented in the chart (300) in a high resistance state, the voltage may be held between zero and roughly 1.1 arbitrary units of voltage to stay within the high resistance region (310). On the other hand, to hold a NDR material that is schematically represented in the chart (300) in a low resistance state, the voltage may be held above 0.5 arbitrary units of voltage to stay within the low resistance region (310).

To switch the NDR material to a different resistance state, the voltage may be moved outside of the overlap between the low and high resistance regions (310, 314). For example, to switch the NDR material to a low resistance state from a high resistance state, the voltage may be moved above the 1.1 arbitrary units. In such a situation, NDR material, such as the NDR material depicted in chart (300), will switch to a low resistance state because the voltage value is outside of the high resistance region (310). Likewise, to switch the NDR material to a high resistance state, the voltage may be dropped to below 0.5 arbitrary units of voltage. In such a situation, NDR material, such as the NDR material depicted in chart (300), will switch to a high resistance state because the voltage value is outside of the low resistance region (310).

Switching between high resistance and low resistance states of the NDR material may be accomplished without the transistor. However, the transistor may limit the amount of current allowed through the NDR material. For example, line (316) may schematically represent the load for writing a “1” into a memory cell with the transistor and NDR material. In the example of FIG. 3, the current of line (316) is maximized at fifteen arbitrary units of current depicting that the p-type semiconductor material of the transistor is limiting the current flow.

In accordance with the example of FIG. 3, line (318) schematically represents values that may be used to write a “0” to the memory cell. Further, line (320) may schematically represent load values that may be used to hold the NDR material within either the high resistance or low resistance states. The holding voltage value may be the same voltage value for holding the NDR material within either the low resistance state or the high resistance state. Such a holding voltage value may be within the overlap (321) between a high resistance region voltage range (322) and a low resistance region voltage range (324). While the holding value may be within an overlap (321) of these ranges (322, 324), the NDR material will remain stable within its existing region as long as the voltages are not moved past the voltage range associated with the existing resistance state. In some examples, hysteresis keeps the NDR material from switching resistance states as long as the voltages remain within the demonstrated voltage ranges (322, 324) even if the holding value is compatible with more than one resistance states.

Line (326) of FIG. 3 schematically represents loads that may be used to apply a voltage to the gate terminal to enable current to pass through the transistor so that a current sensor may measure the current. Based on the current value measured with the current sensor, the memory cell may report a “1” or a “0” in binary information to the source reading the memory cell.

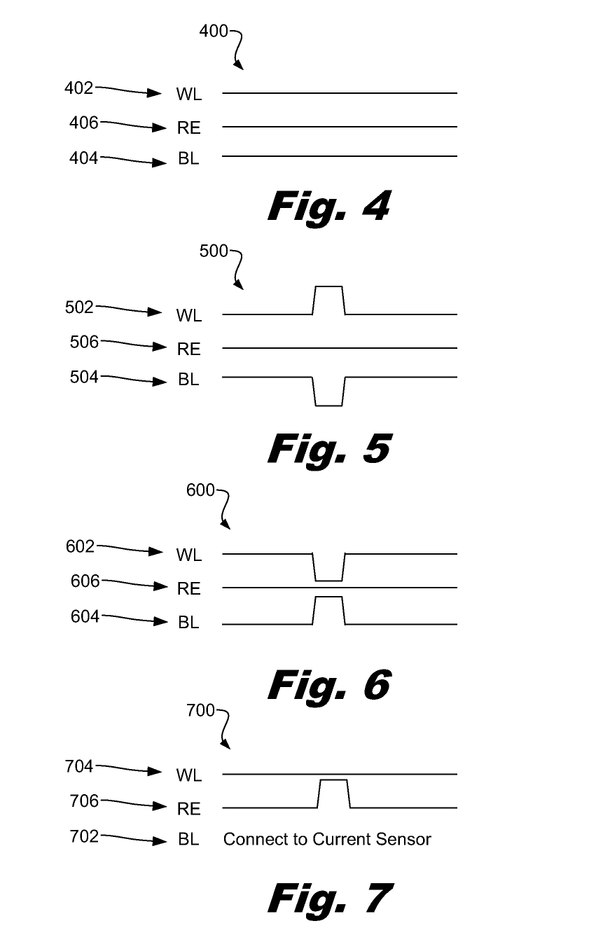

FIG. 4 is a diagram of an illustrative signal profile (400), according to principles described herein. In this example, the signal profile (400) schematically represents holding the NDR material within its existing resistance state. In this example, a write line (402) may be connected to a source/drain terminal of the transistor, a bit line (404) may be connected to the other source/drain terminal of the transistor, and a read enable line (406) may be connected to the gate terminal. A voltage may be applied to each of these lines (402, 404, 406). In the example of FIG. 4, each of the applied voltages is maintained at a constant level.

FIG. 5 is a diagram of an illustrative signal profile (500), according to principles described herein. In this example, the signal profile (500) schematically represents setting the NDR material to a low resistance state. In this example, a voltage applied to the write line (502) is temporarily increased, while a voltage applied to a bit line (504) is temporarily decreased. Such an arrangement makes the overall voltage difference temporarily greater, and as a consequence, the NDR material is switched to a low resistance state. After switching the resistance states, the voltages to both write line (502) and the bit line (504) may return to the holding levels that are schematically depicted in FIG. 4 to hold the NDR material in the low resistance state. The read enable line (506) maintains its holding amount of voltage applied to the gate terminal.

FIG. 6 is a diagram of an illustrative signal profile (600), according to principles described herein. In this example, the signal profile (600) schematically represents resetting the NDR material to a high resistance state. In this example, a voltage applied to the write line (602) is temporarily decreased, while a voltage applied to a bit line (604) is temporarily increased. Such an arrangement makes the overall voltage difference lower, and as a consequence, the NDR material is switched to a high resistance state. After switching the resistance states, the voltages to both write line (602) and the bit line (604) may be returned to the holding levels that are schematically depicted in FIG. 4 to hold the NDR material in the high resistance state. The read enable line (606) maintains its holding amount of voltage applied to the gate terminal.

FIG. 7 is a diagram of illustrative signal profile (700), according to principles described herein. In this example, the signal profile (700) schematically represents reading the resistance state of the NDR material. In this example, the bit line (702) is electrically connected to a current sensor. The write line (704) maintains its voltage while the enable read line (706) has a temporary voltage increase. Such a temporary increase in the voltage applied to the read enable line (706), which is connected to the gate terminal of the transistor, may allow enough current through the transistor to enable the current sensor to determine the resistance state of the NDR material.

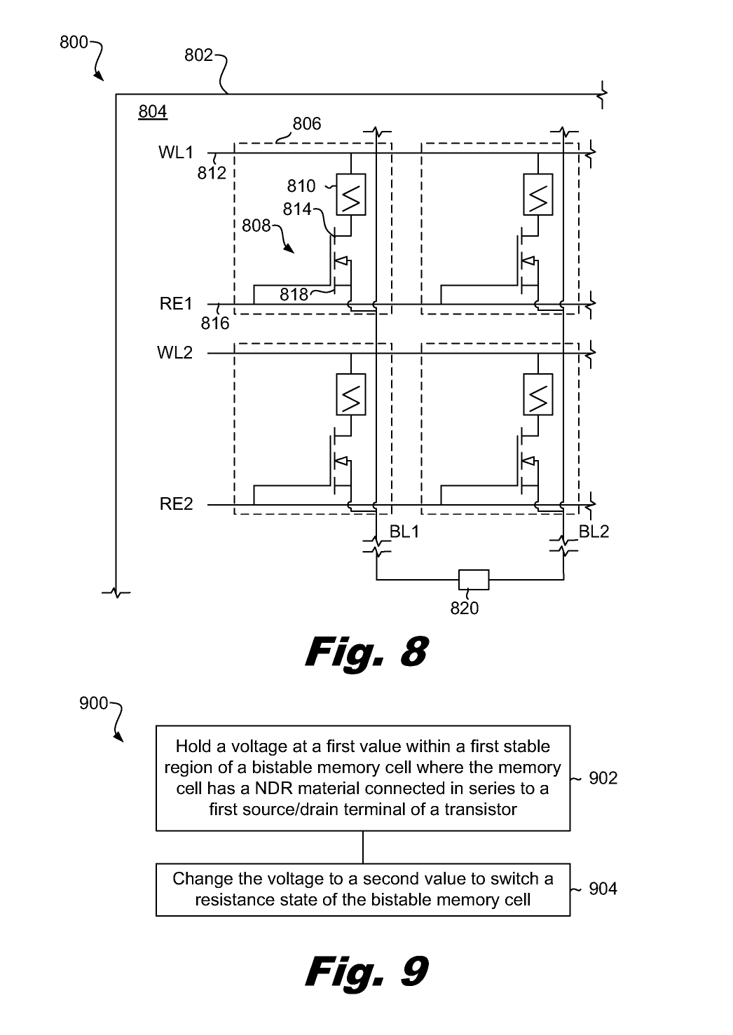

FIG. 8 is a diagram of illustrative circuitry (800) of a memory device (802), according to principles described herein. In this example, the circuitry (800) is incorporated into a processor die (804). In FIG. 8, the circuitry includes arranging multiple memory cells (806) in an array of rows and columns. Each of the memory cells may include a transistor (808) connected in series to NDR material (810). Each memory cell may store a single bit of information, such as a “1” or a “0” in binary information. In some examples, the multiple memory cells (806) are incorporated in an integrated circuit with multiple processor modules.

Every other row (812) may be a write line that is electrically connected to the NDR material (810) of each memory cell (806). Each of the NDR materials (810) may be connected to a source/drain terminal (814) of the transistors (808). The remaining rows (816) may be read enable lines that are electrically connected to the other source/drain terminals (818) of each of the memory cells (806). Both the write lines and the read enable lines may be in electrical communication with a voltage source to apply a voltage to the respective rows.

Further, each of the columns may be bit lines that are used to select the desired memory cell. Each of the bit lines are also connected to voltage sources as well. When it is desired to write memory to a specific memory cell, the respective write line may temporarily apply a positive voltage and the respective bit line may temporarily apply a negative voltage such that the collective voltage changes cause the NDR material (810) to switch resistance states. To hold the NDR material (810) within the existing resistance state, both the write line and the bit lines may return to applying a predetermined holding voltage value.

To read the bit of information in the memory cell (806), the read enable line may temporarily apply an increased amount of voltage, which will energize the gate terminal and allow current to pass thought the transistor (808). The current release may be read with a current sensor (820) that may be located off of the memory although electrically connected to the bit lines. Switching logic may temporarily, electrically connect the bit line to the current sensor (820). In some examples, the same switching logic connects the bit line to a voltage source.

The memory device may be any device that uses memory. For example, a non-exhaustive list of memory devices may include tangible memory storage, computers, electric tablets, laptops, watches, phones, servers, routers, processors, other memory devices, or combinations thereof.

FIG. 9 is a diagram of an illustrative method (900) for storing memory, according to principles described herein. In this example, the method (900) includes holding (902) a voltage at a first value within a stable region of a bistable memory cell where the memory cell has a NDR material connected in series to a first source/drain terminal of a transistor and changing (904) the voltage to a second value to switch the resistance state of the bistable memory cell.

In some examples, the method also includes measuring the resistance state with a current sensor electrically connected to a second source/drain terminal of the transistor. Measuring the resistance state with a current sensor connected to a second source/drain terminal may include changing an electrical conductivity between the first and second source/drain terminals with a gate terminal of the transistor.

Further, the method may include temporarily decreasing the voltage to switch the memory cell to a high resistance state or temporarily increasing the voltage to switch the memory cell to a low resistance state. After decreasing or increasing the voltages, the voltage levels may be returned to holding voltage level to hold the NDR material within its existing resistance state.

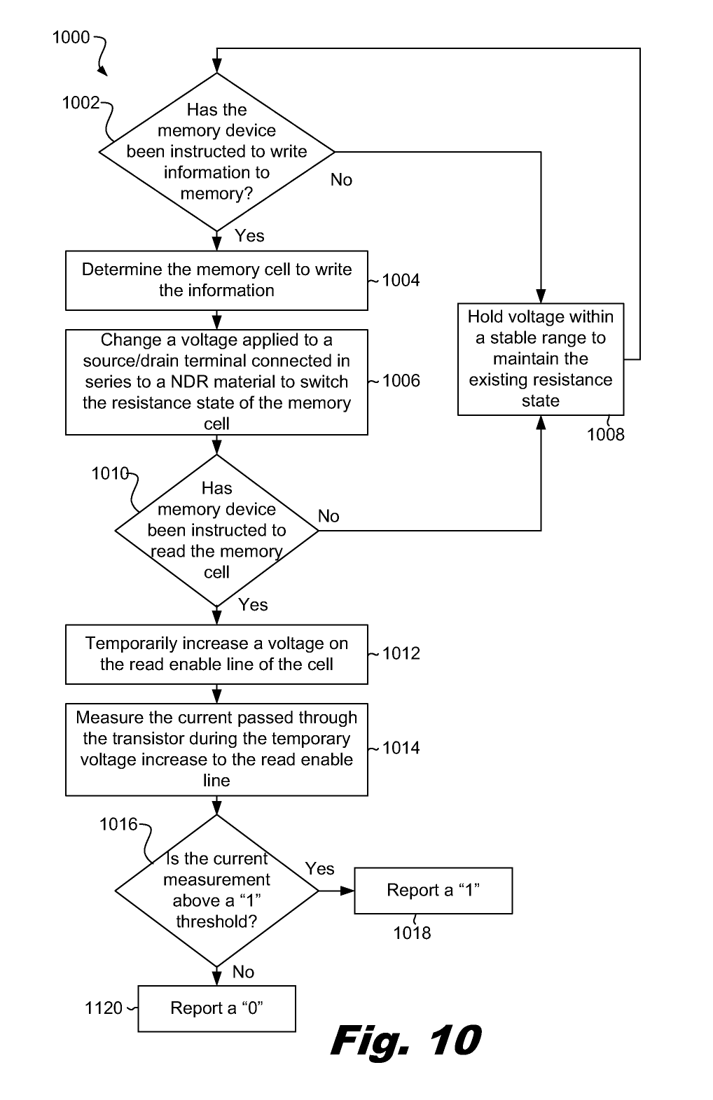

FIG. 10 is a diagram of an illustrative flowchart (1000) of a process for operating a memory device, according to principles described herein. In this example, the process may include determining (1002) whether the memory device has been instructed to write memory.

If the memory device has been instructed to write information to memory, then the memory device may first determine (1004) which memory cell to write the information. Then, the memory device may change (1006) a voltage applied to a source/drain terminal connected in series to a NDR material to switch the resistance state of the memory cell. On the other hand, if the memory device has not been instructed to write memory, then the memory device may hold (1008) a voltage applied to a NDR material within a stable range for the existing resistance state of the NDR material.

The process may also include determining (1010) whether the memory device has been instructed to read the memory cell. If not, the memory device may continue to hold (1008) the voltages within a stable range of the NDR material's existing resistance state. If the memory device has been instructed to read the memory cell, then the memory device may temporarily increase (1012) a voltage on the read enable line of the memory cell. The memory device may measure (1014) the current passed through the transistor during the temporary voltage increase to the read enable line. Then, the process may include determining (1016) whether the current measurement is above a “1” threshold. If the current is above the “1” threshold, then the memory device may report (1018) a “1” in binary information. If the current measured is below the “1” threshold, then the memory device may report a “0” in binary information. In some examples, if NDR material is in a high resistance state, the current sensor measures a specific ampere level, such as 1 ampere. In some examples, if NDR material is in a low resistance state, the current sensor measures a specific ampere level, such as 15 amperes.

While the examples above have been described with specific types of transistors, any type of transistor may be used in accordance with the principles described herein. Also, while the arrangement of the memory cells have been described with specific arrangements, any arrangement of a memory cell may be used in accordance with the principles described herein. While the examples above have been described with particular reference to specific locations of the NDR material in relation to source/drain terminals, p-type semiconductor material, and the gate terminal, any location or arrangement of the NDR material with respect to the locations of the source/drain terminals, p-type semiconductor material, and the gate terminal that are compatible with the principles described herein may be used. While the above examples have been described above with reference to a particular type of semiconductor channel between the first and second source/drain terminals of the transistor, any type of channel compatible with the principles described herein may be used.

While the examples above have been described with specific reference to particular types of NDR materials, any materials exhibiting an NDR characteristic compatible with the principles described herein may be used. While the examples above have been described with specific reference to a specific NDR characteristics and/or load line, materials exhibiting different NDR characteristics and/or load lines may be used in accordance to the principles described herein. Further, while the examples above have been described with reference to specific methods and processes, any method or process compatible with the principles described herein may be used.

While the above examples have been described above with reference to specific ways of writing to memory and reading memory, any way to read and write memory compatible with the principles described herein may be used. Further, while measuring current has been described above with specific reference to specific examples, any method or mechanism for measuring current may be used in accordance with the principles described herein. Also, while the memory device has been described with reference to a particular arrangement of memory cells, any memory cell arrangement compatible with the principles described herein may be used.

The preceding description has been presented only to illustrate and describe examples of the principles described. This description is not intended to be exhaustive or to limit these principles to any precise form disclosed. Many modifications and variations are possible in light of the above teaching.

What is claimed is:

1. A memory cell, comprising:
a transistor with a first source/drain terminal spaced apart from a second source/drain terminal with a semiconductor material;
a gate terminal located proximate said semiconductor material such that an increase in a gate terminal voltage increases a conductivity of said semiconductor material; and
said first source/drain terminal being connected in series to a negative differential resistance material.

2. The memory cell of claim 1, wherein said negative differential resistance material is a current controlled negative differential resistance material.

3. The memory cell of claim 1, wherein said second source/drain terminal is electrically connected to a current sensor.

4. The memory cell of claim 1, wherein said negative differential resistance material is incorporated into a vertical connector connected to said first source/drain terminal.

5. The memory cell of claim 1, wherein said first source/drain terminal is connected to a write line, said second source/drain terminal is connected to a bit line, and said gate terminal is connected to a read enable line.

6. A memory device, comprising:
multiple memory cells arranged in a plurality of rows and a plurality of columns;
each memory cell comprising a transistor with a first source/drain terminal spaced apart from a second source/drain terminal with a semiconductor material and a gate terminal located proximate said semiconductor material; and
said first source/drain terminal being connected in series to a negative differential resistance material.

7. The memory device of claim 6, wherein said memory cells comprise a complementary metal oxide semiconductor circuitry.

8. The memory device of claim 6, wherein said plurality of rows is connected to a current sensor.

9. The memory device of claim 6, wherein said first source/drain terminal is connected to a write line, said second source/drain terminal is connected to a bit line, and said gate terminal is connected to a read enable line.

10. The memory device of claim 6, wherein said multiple memory cells are incorporated in an integrated circuit comprising multiple processor modules.

11. A method for storing memory with negative differential resistance material, comprising:
holding a voltage at a first value within a first stable region of a bistable memory cell where said bistable memory cell comprises a negative differential resistance material connected in series to a first source/drain terminal of a transistor; and
changing said voltage to a second value to switch a resistance state of said bistable memory cell.

12. The method of claim 11, further comprising measuring said resistance state with a current sensor electrically connected to a second source/drain terminal of said transistor.

13. The method of claim 12, wherein measuring said resistance state with a current sensor connected to a second source/drain terminal includes changing an electrical conductivity between said first and second source/drain terminals with a gate terminal of said transistor.

14. The method of claim 11, changing said voltage to a second value to switch a resistance state of said bistable memory cell includes temporarily decreasing said voltage to switch said bistable memory cell to a high resistance state.

15. The method of claim 11, changing said voltage to a second value to switch a resistance state of said bistable memory cell includes temporarily increasing said voltage to switch said bistable memory cell to a low resistance state.
